(19) United States
(12) Patent Application Publication
(10) Pub. No.: US 2026/0104571 A1
(43) Pub. Date: Apr. 16, 2026

(54) MIRROR SYSTEM, MICROLITHOGRAPHIC PROJECTION EXPOSURE APPARATUS COMPRISING A MIRROR SYSTEM

(71) Applicant: Carl Zeiss SMT GmbH, Oberkochen (DE)

(72) Inventors: Willi Anderl, Huettlingen (DE); Paul Buettner, Aalen (DE); Felix Weinbuch, Oberkochen (DE); Simon Lutz, Oberkochen (DE); Igor Altenberger, Oberkochen (DE); Johannes Kruis, Oberkochen (DE)

(21) Appl. No.: 19/412,568

(22) Filed: Dec. 8, 2025

Related U.S. Application Data
(63) Continuation of application No. PCT/EP2024/063200, filed on May 14, 2024.

(30) Foreign Application Priority Data
Jun. 23, 2023 (DE) 10 2023 205 961.4

(51) Int. Cl. G02B 7/18; G02B 5/08; G03F 7/00

(52) U.S. Cl. CPC G02B 7/1815; G02B 5/0891; G03F 7/70033; G03F 7/70075; G03F 7/7015; G03F 7/702; G03F 7/70233; G03F 7/70316; G03F 7/70825; G03F 7/70891; G03F 7/7095

(57) ABSTRACT

A mirror system comprises: an EUV mirror having an optical surface having a high reflectivity for EUV radiation; and a frame structure carrying a system component of the mirror system. The frame structure comprises a structure body and an insert. The insert comprises (or consists of) a material whose thermal properties deviate from the thermal properties of the material of the structure body. A fluid channel for a temperature-regulating fluid is formed in the structure body. The insert is exposed to a heat load during operation of the mirror system. The insert spans a contour line transversely to the direction of the fluid channel so that a cross-sectional portion of the fluid channel is accommodated within the contour line. The disclosure furthermore relates to a microlithographic projection exposure apparatus comprising such a mirror system.

### CROSS-REFERENCE TO RELATED APPLICATIONS

The present application is a continuation of, and claims benefit under 35 USC 120 to, international application No. PCT/EP2024/063200, filed May 14, 2024, which claims benefit under 35 USC 119 of German Application No. 10 2023 205 961.4, filed Jun. 23, 2023. The entire disclosure of each of these applications is incorporated by reference herein.

### FIELD

The disclosure relates to a mirror system and a microlithographic projection exposure apparatus comprising a mirror system.

### BACKGROUND

Microlithography projection exposure apparatuses are utilized for the production of integrated circuits with particularly small structures. A photomask illuminated by very short-wave extreme ultraviolet radiation (EUV radiation) is imaged onto a lithography object in order to transfer the mask structure to the lithography object.

The projection exposure apparatus comprises a plurality of EUV mirrors having an optical surface at which the EUV radiation is reflected. The EUV mirrors have a precisely defined shape and are precisely positioned in order that the imaging of the mask onto the lithography object is of sufficient quality.

Often, the desired imaging quality can only be achieved if the projection exposure apparatus comprises a frame structure that keeps the system components in position relative to one another with sufficient accuracy. During operation of the projection exposure apparatus, various heat loads affect components of the projection exposure apparatus. By way of example, heat is supplied by absorption of EUV radiation, by heating devices or by waste heat in connection with mechanical movement of components of the projection exposure apparatus.

If the frame structure or parts of the frame structure heat(s) up, then a thermal deformation may occur which results in undesirable displacement of components of the projection exposure apparatus relative to one another. This is often accompanied by a reduction of the imaging quality. In order to reduce thermal deformations, the frame structure can be provided with fluid channels through which a temperature-regulating fluid is guided during operation of the projection exposure apparatus. The temperature-regulating fluid can help dissipate heat from the frame structure in order to keep the frame structure at a desired temperature.

A material which is resistant to the influence of the temperature-regulating fluid, i.e. which for example does not corrode, can be used for the structure body of the frame structure in which the fluid channel is formed. However, such materials often have a low thermal conductivity, which can result in the heat transfer into the temperature-regulating fluid being adversely affected. It is known to provide the frame structure with an insert whose thermal properties deviate from the thermal properties of the structure body in order to mitigate undesirable influences of the supplied heat on the frame structure.

### SUMMARY

The disclosure seeks to provide a mirror system and a microlithographic projection exposure apparatus comprising a mirror system in which the frame structure has improved properties under the influence of heat.

In an aspect, the disclosure provides a mirror system comprising: an EUV mirror having an optical surface having a high reflectivity for EUV radiation; and a frame structure carrying a system component of the mirror system. The frame structure comprises a structure body and an insert, wherein the material of the insert has different thermal properties from those of the material of the structure body. A fluid channel for a temperature-regulating fluid is formed in the structure body. The insert is configured to be exposed to a heat load during operation of the mirror system. The insert spans a contour line transversely to the direction of the fluid channel, so that a cross-sectional portion of the fluid channel is accommodated within the contour line.

The term contour line of the insert denotes a line extending within a plane oriented transversely to the direction of the fluid channel. A cross-sectional portion of the fluid channel is deemed to be accommodated within the contour line if there is a straight line connecting two points of the contour line so that the cross-sectional portion is enclosed between the contour line and the straight line.

In the case of the mirror system according to the disclosure, the structure body can comprise (or consist of) a material having a high resistance vis-à-vis contact with the temperature-regulating fluid, while the insert can comprise (or consist of) a material whose thermal properties are more desirable than the thermal properties of the structure body material. By virtue of the insert having a surface shape adapted to the fluid channel, the material having desirable thermal properties is brought closer to the fluid channel, with the result that the heat introduced via the insert has a relatively small negative effect on the frame structure.

In one embodiment, the material of the insert has a higher thermal conductivity than the material of the structure body. By virtue of the insert being adapted to the shape of the fluid channel, a larger area can be available via which heat from the insert can pass over to the temperature-regulating fluid. The thermal deformation of the frame structure can decrease on account of an improved heat transfer into the temperature-regulating fluid.

The temperature-regulating fluid can be a temperature-regulating liquid, for example water. Appropriate materials which are resistant vis-à-vis permanent contact with water are for example high-grade steel materials, such as for example Cr steels. The use of aluminium alloys or ceramic materials is also possible. The material of the structure body can have a relatively low thermal conductivity, which for example can be less than 200 W/(K*m), such as less than 50 W/(K*m), for example less than 20 W/(K*m).

No particular corrosion resistance is required for the material of the insert. By way of example, copper, aluminium, ceramic, composite materials are appropriate as material for the insert. The thermal conductivity of the material of the insert can be higher than the thermal conductivity of the material of the structure body. By way of example, the thermal conductivity of the material of the insert can be greater than 200 W/(K*m), such as greater than 300 W/(K*m).

In addition or as an alternative thereto, the material of the insert can have a lower coefficient of thermal expansion than the material of the structure body. A relatively low coefficient of thermal expansion can have a positive effect even without improved heat transfer, since only a small deformation of the frame structure is established despite heating of the material. The coefficient of thermal expansion of the material of the insert can be for example less than 5×10⁻⁶ K⁻¹, such as less than 2*10⁻⁶ K⁻¹. An example of a material having a low coefficient of thermal expansion is an iron-nickel alloy known by the designation Invar.

The cross-sectional portion of the fluid channel which is accommodated within the contour line can be greater than 40%, such as greater than 60%, for example greater than 80%, of the cross-sectional area of the fluid channel. Proceeding from the central axis of the fluid channel, there can be a segment of the cross section of the fluid channel in which the fluid channel is not surrounded by the insert. The angle over which the segment extends can be less than 180°, such as less than 120°, for example less than 90°.

The contour line can be composed of a plurality of rectilinear sections. It is also possible for the contour line to have a rounded shape adapted to the fluid channel. In the context of the disclosure, it is often desirable for the distance between the wall of the fluid channel and the insert to be relatively small. By way of example, the distance can be between 0.3 mm and 10 mm, such as between 0.5 mm and 5 mm, for example between 0.7 mm and 2 mm. If the distance varies over the circumference of the fluid channel, then the specification relates to the smallest distance between the wall of the fluid channel and the insert.

The insert can be available as a finished component before it is connected to the structure body. The connection between the insert and the structure body can be produced using a suitable connection method. By way of example, the connection can be effected by diffusion welding, by some other welding method or by soldering. Adhesive bonding and other connection methods are also possible.

In an embodiment, the insert of the structure body can be produced by additive manufacturing. The material of the insert is added to the structure body, with the result that the shape of the insert arises in the course of the additive manufacturing process. The material of the insert can be added in powder form, for example, to the structure body. A solid internal structure of the material can be produced for example by laser melting, by application of ultrasound and/or by generation of friction.

In all cases, the frame structure can be designed such that the structure body performs a supporting function, that is to say that the insert by itself is not an independently supporting structure.

The structure body can be provided with a recess that matches the shape of the insert. The recess can be free of undercuts in an insertion direction. In the case of an insert available as a finished component, this means that the insert can be inserted into the recess without formation of cavities in the frame structure that arises. By way of example, the insertion direction can be oriented perpendicularly to the direction of the fluid channel or parallel to the direction of the fluid channel. In the case of additive manufacturing, too, the production of the insert is facilitated if there are no undercuts in the direction in which the material is built up. The recess can be designed to taper in the insertion direction. The taper can extend over part of the insertion path or over the entire insertion path. In the latter case, the insert can be inserted into the structure body without necessitating a sliding movement between a surface of the insert and a surface of the structure body.

The insertion direction or, in the case of additive manufacturing, the build direction can be oriented transversely to the direction of the fluid channel. It is also possible for the insertion direction/build direction to be parallel to the direction of the fluid channel. If the insertion direction/build direction is parallel to the fluid channel, then the insert can have an undercut transversely with respect thereto, which makes it possible to design the insert to wrap around the fluid channel to a more pronounced extent.

The contour line can span a plane which is at right angles to an axis of the fluid channel. The plane lies in the section of the fluid channel in which the cross-sectional portion of the fluid channel is accommodated within the contour line. The fluid channel can comprise a section which extends in the longitudinal direction of the fluid channel and in which the fluid channel is accommodated, in the sense according to the disclosure, within the contour line of the insert. The section can comprise at least 30%, such as at least 50%, for example at least 70%, of the distance that the fluid channel extends within the structure body.

The structure body can comprise a plurality of fluid channels or a plurality of fluid channel portions which extend within the structure body. The fluid channel portions can be disposed in parallel. This is the case for example if the fluid channel portions extend between an input manifold and an output manifold. Fluid channel portions disposed in series are also possible.

The insert can be designed to cover an area spanned by a plurality of fluid channels and/or fluid channel portions. The insert can be shaped such that each of the fluid channels and/or fluid channel portions has a cross-sectional portion accommodated within a contour line of the insert. One or more of the features disclosed in the context of the first fluid channel can apply to all fluid channels and/or fluid channel portions.

The structure body can be a body comprise a uniform material, such that the propagation of heat within the structure body substantially depends on the material properties. In order to be able to better control the thermal state of the structure body, provision can also be made of measures that prevent the propagation of heat in specific directions. By way of example, the structure body can be provided with heat barriers that obstruct the propagation of heat. In one embodiment, the heat barriers can be configured as cavities. In addition or as an alternative thereto, further components such as for example sensors, heating elements or heat pipes can be integrated in the structure body. The disclosure also encompasses frame structures comprising a plurality of inserts. Each of the inserts can comprise one or more of the features described in the context of the first insert.

The frame structure according to the disclosure can fulfill various functions within a microlithographic projection exposure apparatus. The frame structure can be for example a frame structure which carries components of the illumination system of a microlithographic projection exposure apparatus. In one embodiment, the frame structure carries a plurality of EUV mirror elements, for example a plurality of EUV mirror elements of a facet mirror, via the insert. In other words, the mirror elements are attached to the insert, such that mechanical forces proceeding from the mirror elements are introduced into the frame structure via the insert.

The frame structure can be a frame structure which, in addition or as an alternative thereto, carries components of the projection lens of a microlithographic projection exposure apparatus. By way of example, the frame structure can carry an EUV mirror of the projection lens via the insert. Actuators can be provided which can alter the position and/or the orientation of the EUV mirror relative to the frame structure.

In addition or as an alternative thereto, the frame structure can carry sensors via the insert. The sensors can be designed to obtain information about the position and/or orientation of an EUV mirror, for example information about the position and/or orientation of an EUV mirror of a projection lens. It is also possible for the sensors to be designed to obtain temperature information for example about the local temperature of the frame structure. Such temperature information can be used to estimate the expected position of an EUV mirror.

In addition or as an alternative thereto, the frame structure can carry a heating device. The heating device can be designed to supply heat to an EUV mirror, such as an EUV mirror of a projection lens. The heat can be guided to the EUV mirror in a non-contact fashion, for example in the form of infrared radiation. The heating device can be attached to the insert. For example, the heating device can be carried by the frame structure via the insert. The insert can be surrounded all around by the fluid channel.

In an aspect, the disclosure provides a projection lens comprising a plurality of EUV mirrors used to image a photomask into an image plane. At least one of the EUV mirrors of the projection lens is an EUV mirror of a mirror system according to the disclosure, wherein the mirror system forms a constituent part of the projection lens.

In an aspect, the disclosure provides an illumination system, comprising a plurality of EUV mirrors used to illuminate a photomask with EUV light. At least one of the EUV mirrors of the illumination system is an EUV mirror of a mirror system according to the disclosure, wherein the mirror system forms a constituent part of the illumination system. In an aspect, the disclosure provides a microlithographic projection exposure apparatus comprising such a mirror system, comprising such a projection lens and/or comprising such an illumination system.

### BRIEF DESCRIPTION OF THE DRAWINGS

The disclosure is described by way of examples below on the basis of certain embodiments with reference to the accompanying drawings, in which:

FIG. 1: shows one embodiment of a projection exposure apparatus according to the disclosure;

FIG. 2: shows one embodiment of a mirror system according to the disclosure;

FIG. 3: shows a detail from FIG. 2 in an enlarged illustration;

FIG. 4: shows a detail from FIG. 2 in an alternative embodiment of the disclosure;

FIG. 5: shows the view in accordance with FIG. 4 in an alternative embodiment of the disclosure;

FIG. 6: shows an embodiment of a mirror system according to the disclosure;

FIG. 7: shows a detail from FIG. 6 in an enlarged illustration;

FIG. 8: shows an embodiment of a mirror system according to the disclosure;

FIG. 9: shows a detail from FIG. 8 in an enlarged illustration;

FIG. 10: shows an embodiment of a mirror system according to the disclosure;

FIG. 11: shows a detail from FIG. 10 in an enlarged illustration;

FIG. 12: shows a component of a mirror system according to the disclosure in an alternative embodiment of the disclosure.

### DETAILED DESCRIPTION

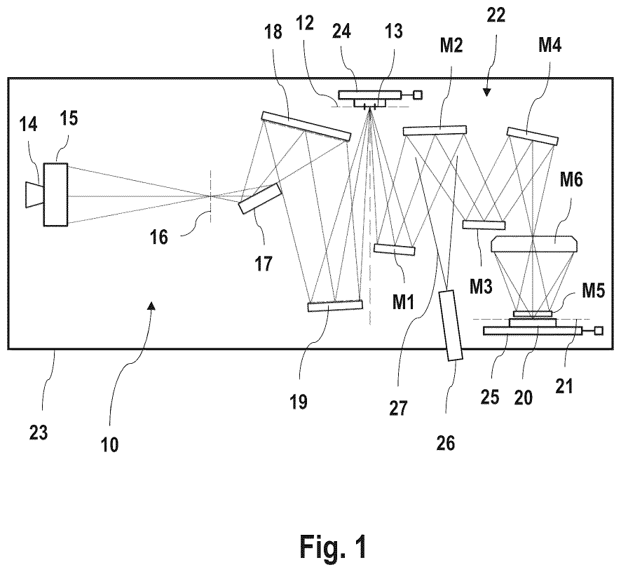

FIG. 1 schematically illustrates a microlithographic EUV projection exposure apparatus. The projection exposure apparatus comprises an exposure beam source 14, an illumination system 10 and a projection lens 22, which are operated jointly in a vacuum chamber 23. Negative pressure prevails in the vacuum chamber 23 during the operation of the EUV projection exposure apparatus.

The exposure beam source 14 generates electromagnetic radiation in the EUV range, such as at a wavelength of between 5 nm and 30 nm for example. The exposure radiation emanating from the exposure beam source 14 is focused into an intermediate focal plane 16 by way of a collector 15. Exposure radiation passing across the intermediate focal plane 16 is guided into an object plane 12 by the illumination system 10, with the result that an object field in the object plane 12 is illuminated with uniform radiation intensity.

The illumination system 10 comprises a deflection mirror 17 used to deflect the exposure radiation to a first facet mirror 18. A second facet mirror 19 is disposed downstream of the first facet mirror 18. The second facet mirror 19 is used to image the facets of the first facet mirror 18 into the object plane 12.

A photomask 13 is arranged in the object plane 12, and is imaged into an image plane 21 by way of a plurality of mirrors M1-M6 of the projection lens 22. A structure formed on the photomask 13 is transferred to a radiation-sensitive layer of a wafer 20 arranged in the image plane 21. The photomask 13 is suspended from a first scanning device 24, and the wafer 20 is at rest on a second scanning device 25 such that the wafer 20 can be exposed in a scanning procedure during which the photomask 13 and the wafer 20 are moved synchronously with one another.

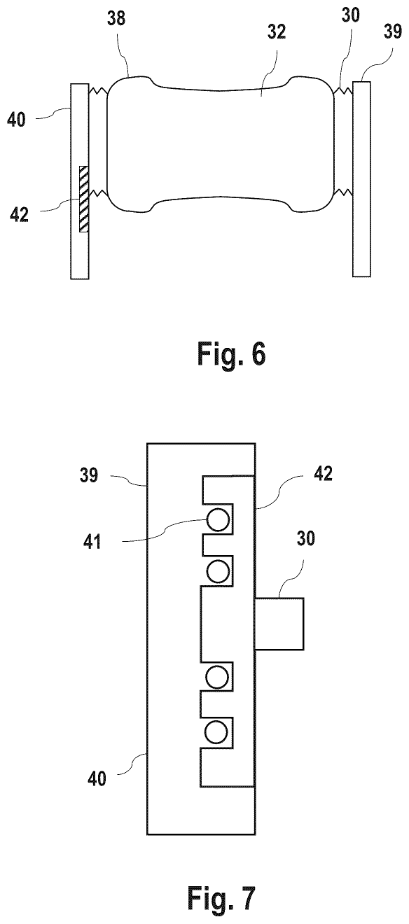

FIG. 6 shows a mirror system, in which a mirror body 38 of a mirror M1-M6 is held on a frame structure 39 using actuators 30. The actuators 30 can be used to alter the position of the mirror body 38 relative to the frame structure 39 for the purpose of orienting and positioning the mirror body 38. An optical surface 32 at which EUV radiation is reflected is formed on the mirror body 38.

The projection exposure apparatus comprises a heating device 26 designed to direct infrared radiation 27 at the reflection surface of an EUV mirror M1-M6 of the projection lens 22 in order to heat the EUV mirror 20, such that the temperature of the EUV mirror M1-M6 is brought to a target value.

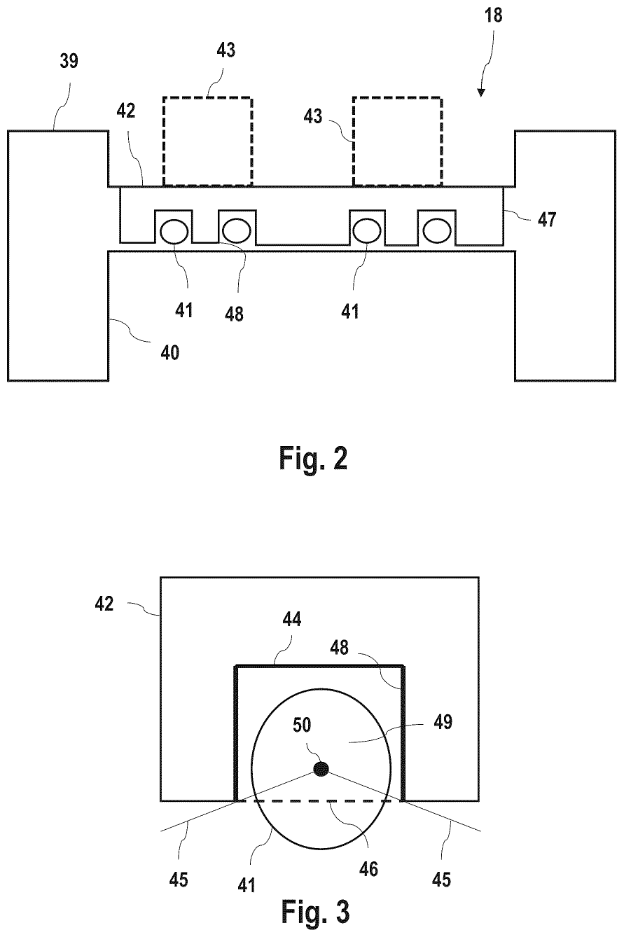

FIG. 2 shows a schematic illustration of the first facet mirror 18. Out of the in actual fact larger number of EUV mirror elements, FIG. 2 shows two mirror elements 43 carried by a frame structure 39. The frame structure 39 comprises a structure body 40 and an insert 42. A plurality of fluid channels in the form of cooling channels 41 are formed in the structure body 40, the channels extending through the structure body 40 between an inlet opening and an outlet opening. The EUV mirror elements 43 are carried by the insert 42.

During operation of the projection exposure apparatus, heat is dissipated from the EUV mirror elements 43. A heat flow arises which proceeds from the EUV mirror elements 43 and extends right into the cooling channels 41 via the insert 42. A cooling liquid, for example water, is guided through the cooling channels 41. Via the wall of the cooling channels 41, heat is transferred to the cooling liquid and dissipated from the frame structure 39.

The structure body 40 in which the cooling channels 41 are formed comprises (or consists of) a material having a good resistance vis-à-vis the cooling liquid. In the exemplary embodiment, the structure body 40 comprises (or consists of) a stainless high-grade steel material having a low thermal conductivity. It is also possible for the structure body 40 to comprise (or consist of) other materials, such as for example aluminium or ceramic materials. In order to improve the heat transfer, an insert 42 is incorporated in the structure body 40, and is seated in a recess 47 of the structure body 40. The insert 42 comprises (or consists of) copper and hence of a material having a significantly higher thermal conductivity than the high-grade steel material of the structure body 40. The copper material has no direct contact with the cooling liquid and thus has no influence on the corrosion behaviour of the cooling duct. According to the disclosure, the insert 42 is shaped such that the cooling channels 41 are accommodated as closely as possible within depressions 48 of the insert 42. The depressions 48 extend along the cooling channels 41, such that a large part of the length of the cooling channels 41 within the structure body 40 lies in the depressions 48.

As shown by the enlarged illustration in FIG. 3, a contour line 44 (illustrated with a thicker line) is spanned by the depression 48, such that a cross-sectional portion 49 of the cooling channel 41 is accommodated within the contour line 44. In FIG. 3, the cross-sectional portion 49 is delimited by a straight line 46 connecting two points of the contour line 44 to one another. The straight line 46 lies below the central axis 50 of the cooling channel 41, which is tantamount to the cross-sectional portion 49 accommodated within the contour line 44 constituting more than half of the cross-sectional area of the cooling channel 41. FIG. 3 furthermore shows that the segment 45 of the cooling channel 41 which is not accommodated within the contour line 44 of the insert 42 extends over less than 180°. The distance between the wall of the cooling channel 41 and the insert 42 is less than 1 mm.

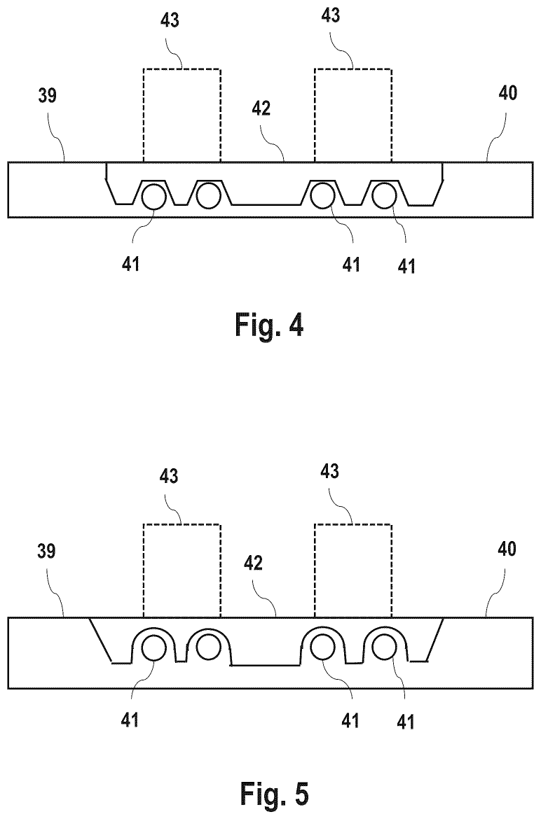

FIG. 4 shows a variant in which the projecting structures of the insert 42 taper in a wedge-shaped fashion at the lower end. The taper facilitates insertion of the insert 42 into the recess of the structure body 40, since the insert 42 automatically centres itself by way of the wedge surfaces. In FIG. 5, the shape of the insert 42 tapers over the entire insertion path. The depressions 48 in the insert 42 have a rounded shape and are thus better adapted to the cross section of the cooling channels 41.

FIG. 6 shows a mirror system of the projection lens 22, in which an EUV mirror M1-M6 is held on a frame structure 39. Position and orientation of the EUV mirror M1-M6 of the mirror body 38 relative to the frame structure 39 can be altered using actuators 30.

As is indicated schematically in FIG. 6 on the basis of the example of one of the actuators 30, the actuators 30 are attached to an insert 42 seated in a recess of the structure body 40 of the frame structure 39. In accordance with the enlarged illustration in FIG. 7, in a manner similar to that in the previous embodiments, the insert 42 has depressions adapted to the cooling channels of the structure body 40. The depressions span a contour line within which the cooling channels 41 lie. In this embodiment, the entire cross section of the cooling channels 41 is accommodated within the contour line.

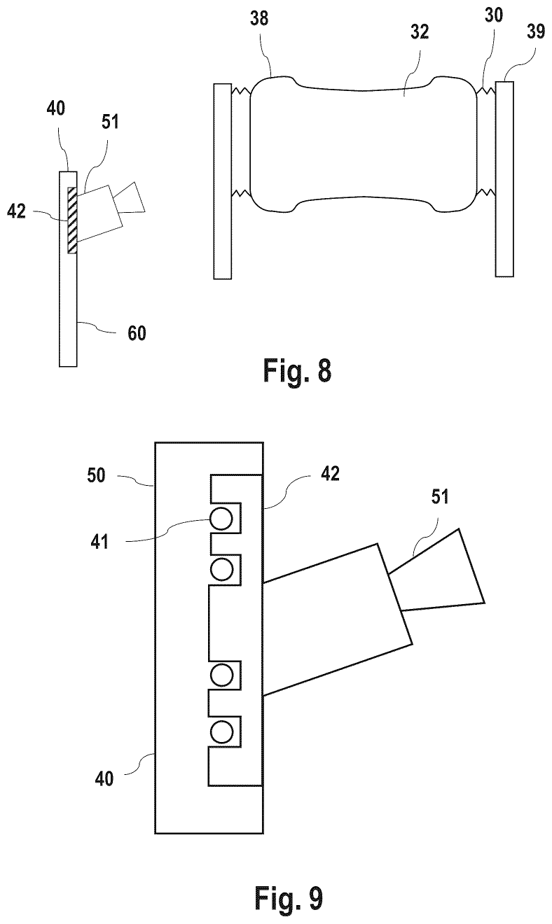

In FIG. 8, the mirror system comprises a second frame structure 60, which carries a sensor 51. The position of the mirror body 38 is ascertained by the sensor 51. The measurement values are fed into a control unit of the mirror system, such that the control unit can control the actuators 30. The sensor 51 is held on an insert 42 inserted into a depression of the structure body 40. In accordance with FIG. 9, the insert 42 spans contour lines within which the cooling channels 41 of the structure body 40 are accommodated. Heat loads to which the sensor 51 is exposed during operation of the projection exposure apparatus, or heat generated by the operation of the sensor 51, is introduced into a cooling liquid flowing through the cooling channels 41, via the insert 42 comprising (or consisting of) a material having a high thermal conductivity.

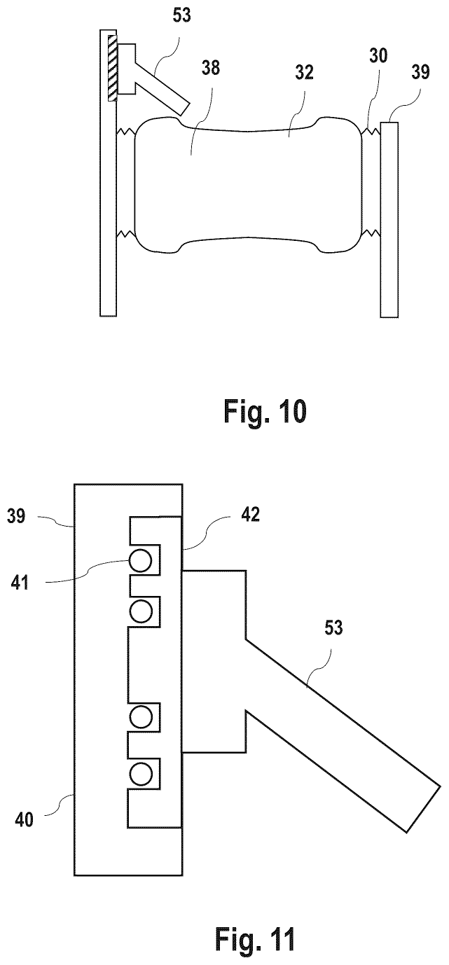

In the embodiment shown in FIG. 10, a heating device 53 is attached to the frame structure 39 and directs infrared radiation at the mirror body 38 in order to heat the mirror body 38. In accordance with FIG. 11, the heating device is attached to an insert 42 seated in a recess of the structure body 40. In a manner similar to that in the previous embodiments, heat that has accumulated in the heating device 53 is introduced into the cooling channels 41 via the insert 42.

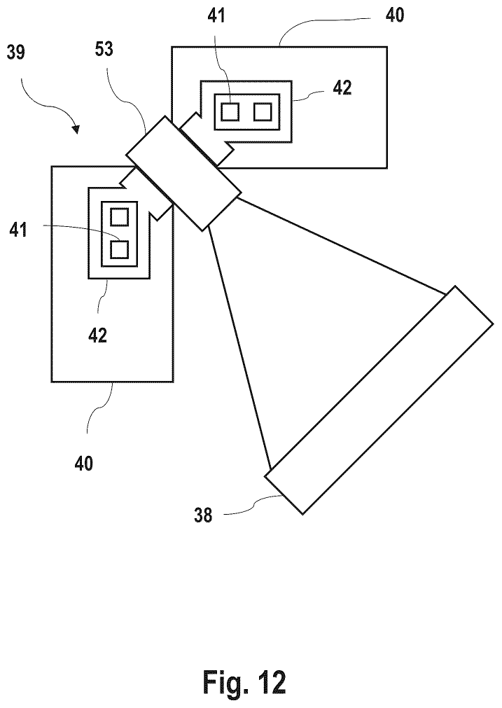

FIG. 12 shows an embodiment in which the frame structure 39 comprises two structure bodies 40, between which the heating device 53 is arranged. Each of the structure bodies 40 is provided with an insert 42 extending in a ring-shaped fashion around cooling channels 41 formed in the structure body 40. In this way, the inserts 42 each span a contour line within which two cooling channels 41 are accommodated. The heating device 53 is connected to the structure bodies 40 via the inserts 42, such that the heating device 53 is carried jointly by the two structure bodies 40. Quantities of heat that have accumulated in the heating device 53 can be emitted to the cooling channels 41 in both directions.

1. A mirror system, comprising:
an EUV mirror comprising an EUV reflective optical surface;
a frame structure supporting a component of the EUV mirror,
wherein:
the frame structure comprises a structure body comprising a material having thermal properties;
the frame structure comprises an insert comprising a material having thermal properties;
the thermal properties of the material of the insert deviate from the thermal properties of the material of the structure body;
the structure body comprises a fluid channel configured to have a temperature-regulating fluid flow therethrough;
the insert is configured to be exposed to a heat load during operation of the mirror system; and
the insert spans a contour line transversely to a direction of the fluid channel so that a cross-sectional portion of the fluid channel is accommodated within the contour line.

2. The mirror system of claim 1, wherein the material of the insert has a higher thermal conductivity than the material of the structure body.

3. The mirror system of claim 2, wherein the material of the structure body has a thermal conductivity of less than 200 W/(K*m).

4. The mirror system of claim 2, wherein the material of the insert has a thermal conductivity of greater than 200 W/(K*m).

5. The mirror system of claim 1, wherein the material of the insert has a coefficient of thermal expansion of less than 5×10⁻⁶ K⁻¹.

6. The mirror system of claim 1, wherein the cross-sectional portion of the fluid channel accommodated within the contour line is more than 40% of a cross-sectional area of the fluid channel.

7. The mirror system of claim 1, wherein a segment a cross section of the fluid channel sections is not surrounded by the insert, and the segment extends over an angle of less than 180°.

8. The mirror system of claim 1, wherein the fluid channel comprises a wall, and a distance between the wall of the fluid channel and the insert is between 0.3 mm and 10 mm.

9. The mirror system of claim 1, wherein the structure body comprises a recess which is free of undercuts in an insertion direction.

10. The mirror system of claim 9, wherein the recess tapers in the insertion direction.

11. The mirror system of claim 1, wherein the fluid channel is accommodated within the contour line of the insert over at least 30% of a length of the fluid channel within the structure body.

12. The mirror system of claim 1, further comprising a heating device carried by the frame structure.

13. The mirror system of claim 1, wherein the fluid channel is surrounded all around by the insert.

14. The mirror system of claim 1, wherein the mirror system is configured so that, during operation of the mirror system, heat is dissipated from the component via the insert and into the fluid channel.

15. The mirror system of claim 1, wherein the EUV mirror comprises an EUV facet mirror, and the component comprises a facet of the EUV facet mirror.

16. The mirror system of claim 1, wherein the material of the structure body has a thermal conductivity of less than 200 W/(K*m).

17. The mirror system of claim 1, wherein the material of the insert has a thermal conductivity of greater than 200 W/(K*m).

18. The mirror system of claim 1, wherein the material of the insert has a coefficient of thermal expansion of less than 5×10⁻⁶ K⁻¹.

19. An apparatus, comprising:
a mirror system according to claim 1,
wherein the apparatus is a microlithographic projection exposure apparatus.

20. The apparatus of claim 19, further comprising an illumination system and a projection lens, wherein the projection lens comprises the mirror system or the illumination system comprises the mirror system.
